(19) United States
(12) Patent Application Publication
(10) Pub. No.: US 2008/0070492 A1
(43) Pub. Date: Mar. 20, 2008

(54) Cooling System for Equipment and Network Cabinets and Method for Cooling Equipment and Network Cabinets

(75) Inventors: Peter Koch, Vilgertshofen (DE); Heiko Ebermann, Dresden (DE)

Correspondence Address: HARNESS, DICKEY & PIERCE, P.L.C., P.O. BOX 828, BLOOMFIELD HILLS, MI, 48303, US

(73) Assignee: KNUERR AG, Arnstorf (DE)

(21) Appl. No.: 11/662,320

(22) PCT Filed: Aug. 29, 2005
(86) PCT No.: PCT/EP05/09299

§ 371 Date: Sep. 26, 2007

(30) Foreign Application Priority Data
Oct. 11, 2004 (DE) 10 2004 049 487.8

(51) Int. Cl. H05K 5/00

(52) U.S. Cl. 454/184; 62/259.2

(57) ABSTRACT

The invention relates to a cooling system for equipment and network cabinets, particularly server cabinets, and to a method for cooling equipment and network cabinets. The cabinets have an airtight construction and are provided with an atmospheric humidity stabilization in order to avoid damage as a result of condensate formation and a reduction of the absolute atmospheric humidity. According to the invention the atmospheric humidity stabilization is brought about by a clearly defined and in particular controllable external air supply and a possible removal of air from the closed cooling air circuit.

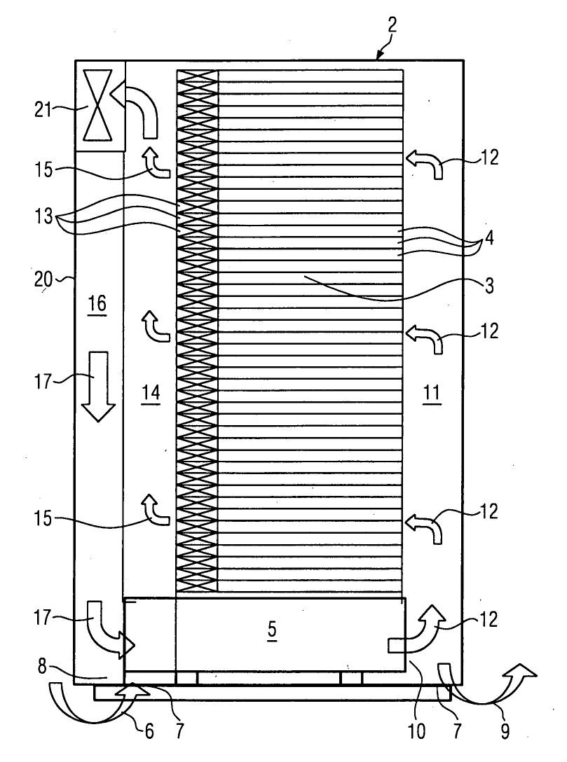

The invention relates to a cooling system for equipment and network cabinets according to the preamble of claim 1 and to a method for cooling equipment and network cabinets according to the preamble of claim 11.

The invention is particularly suitable for server cabinets, which have as electronic modular units a plurality of superimposed or also juxtaposed servers.

It is known to design server cabinets allowing no change of air with the ambient air. As a rule these server cabinets or also network cabinets are almost completely sealed against the environment and e.g. satisfy an IP 55 protection value, i.e. they are constructed in dusttight and hosewater-proof or spraywater-proof manner. Whereas the sealing against jet or hose water is not absolutely vital, an airtight design, which prevents an exchange of air between the interior of the cabinet and the installation room is sought. To this end e.g. correspondingly effective seals are provided in the area of the cable entries and exits and the cabinet manufacturer expressly refers to a complete sealing in this area prior to the putting into operation of the cabinet and the cabinet air conditioning.

Heat removal from the electronic modular units in the interior or installation room of an airtight cabinet takes place with the aid of a closed air flow and a heat exchanger, in which the dissipated power of the electronic modular units is removed.

For cabinets with high-power processors and more particularly for server cabinets with particular advantage air-water heat exchangers can be used for removing the considerable dissipated power and said heat exchangers are connected to the cold water supply of the building. The entire dissipated power of the cabinets loses its heat through the building cold water system and a heat transfer between the installation room and the cabinets is avoided, which can lead to a considerable cost saving due to the lower demands made on the room air conditioning and to a higher installation room occupancy.

Locally there can be a drop below the dew-point within the heat exchanger. The use of cooling water with a temperature below 12° C. and/or a high atmospheric humidity in the installation room can be linked with a condensate formation within the heat exchanger. As a result the absolute atmospheric humidity within the equipment cabinet is reduced, which can lead to damage to the installed modular units and systems.

The object of the invention is to provide a cooling system and a method for cooling equipment and network cabinets, particularly server cabinets, which avoids the disadvantages of condensate formation whilst providing an extremely high and efficient cooling capacity.

With respect to the cooling system the object is inventively achieved by the features of claim 1 and with respect to the cooling method by the features of claim 11. Appropriate and advantageous developments appear in the subclaims and are described in the specific description relative to the drawing.

The cooling system according to the invention is based on an airtight cabinet with a closed cooling air circuit and provides for a stabilization of the atmospheric humidity in the cabinet with the aid of a clearly defined external air supply, which can in particular be controlled.

From the method standpoint the atmospheric humidity in the housing is maintained within the given limits. By increasing again the absolute atmospheric humidity reduced by a condensation process, damage to the installed equipment, components and systems is avoided.

Advantageously the stabilization of the atmospheric humidity is only performed to the extent necessary for a reliable operation of the installed electronics. To avoid a continuous dehumidification of the air, external air is supplied in a defined manner in the cabinet.

For supplying the external air it is possible to provide in planned form interruptions or leaks in the cabinet, e.g. in the covering parts such as the base, cover, back and front door. By means of said leaks or openings external air can be introduced for the controllable influencing of the atmospheric humidity in the cabinet.

From the method standpoint it is appropriate to measure the atmospheric humidity in the cabinet or the cooling air flow and as a function of the ambient conditions and target values in the cabinet to design the leaks or interruptions in such a way that the necessary external air quantity can enter the cabinet interior.

In particularly advantageous manner for a clearly defined external air supply differential pressures between the cabinet interior or closed cooling air circuit and the cabinet environment can be utilized. For example, the leaks or interruptions can be formed in the vicinity of a fan. On the suction side of the fan, where there is an underpressure compared with the cabinet environment, it is possible to form an opening or leak for an external air supply. In an area where overpressure with respect to the environment prevails, there can be an air outlet from the cabinet. By using the different local pressure ratios in planned manner for stabilizing the atmospheric humidity in the cabinet interior, the need for additional fans is avoided.

Advantageously the interruptions or leaks can be provided in the vicinity of the cable entry and/or cable exit, in that e.g. the seals provided here are so constructed that external air can enter or air from the cabinet interior can escape.

Another possibility consists of constructing the sealing profiles in such a way that a seal below IP 55 is formed and water vapour can enter and exit in clearly defined quantities.

As a result of the inventive atmospheric humidity stabilization it is possible to avoid the disadvantages of condensate formation and dehumidification below a given value or range and as a result damage to equipment and systems is avoided.

The invention is described in greater detail hereinafter relative to the single, highly diagrammatic drawing showing an equipment and network cabinet 2 with an inner area 3 for electronic modular units 4.

In the present example servers are stacked in superimposed manner as electronic modular units 4 and are received in a not shown housing with air inlets and outlets. In the present embodiment in each case a fan 13 is located in the housings of the modular units 4. By means of an air circulation with air paths of equal lengths and therefore identical flow resistances for the individual electronic modular units 4 and an aerodynamic separation between the cold supply air 12 and the heated exhaust air 9 the electronic units 4 are supplied with air 12 having a uniform supply air temperature, which is understood to mean a temperature with variations of +/−2° Kelvin.

At the bottom an air-water heat exchanger is provided as heat exchanger 5 and to it is supplied for heat removal purposes air circulated in a closed circuit. The supply air 12 cooled in heat exchanger 5 passes via a supply air duct 11 to the individual electronic modular units 4, absorbs the heat produced by the same and reaches a first exhaust air duct 14 as heated exhaust air. In said first exhaust air duct 14 is collected the exhaust air of the individual electronic modular units 4 and is supplied as a rising exhaust air flow 15 to a second exhaust air duct 16 with the aid of at least one ventilator 21. In a falling exhaust air flow 17 the exhaust air reaches heat exchanger 5 and is cooled there with the aid of cooling water from the cold water supply of the building.

For stabilizing the absolute atmospheric humidity in the vicinity or area of a base 18 or in a bottom, more particularly lateral area of the heat exchanger 5 leaks or interruptions 7 are formed by means of which an external air supply 6 to the closed cooling air circuit can take place. The drawing shows that the external air supply 6 takes place in an underpressure area 8, namely on the suction side of a ventilator 21 in the exhaust air flow 15, whereas at the exit side of the ventilator 21, e.g. following the heat exchanger 5 in the cooled supply air 12 an overpressure area 10 is formed from which by means of leaks or interruptions 7, openings and such things formed here, air can be removed.

If in a lower area 18 of the equipment cabinet 2, e.g. laterally alongside the heat exchanger 5, a not shown shaft is formed and which is also constructed for the running of wires or for cable entry and/or exit (not shown), the external air supply 6 can also be implemented by means of a less tight construction of said cable entry and/or exit or with the aid of openings in the shaft walls (not shown).

Alternatively or additionally further leaks, e.g. clearly defined openings, can also be formed in the vicinity or area of a front door 23 and/or back door 20.

A predeterminable or controllable external air supply can also take place by means of openings, which are provided with a clearly defined filter.

The invention is not limited to the server cabinets described in the embodiment having an air circulation with identically long air paths and an aerodynamic separation of the supply air and exhaust air and can instead be used for all equipment and network cabinets with a closed cooling air circuit.

1-19. (canceled)

20. Assembly for air conditioning of electronic modular units arranged in an inner area of an equipment and network cabinet, having a closed cooling air circuit and a heat exchanger for dissipating the heat loss produced by the electronic modular units, wherein
in the vicinity of covering parts of the cabinet openings, interruptions or leaks formed in planned manner are provided and through which external air can be supplied in order to stabilize the atmospheric humidity in the inner area of the cabinet.

21. Assembly according to claim 20, wherein
the leaks in the cabinet are formed in areas where different pressures prevail inside and outside the cabinet.

22. Assembly according to claim 20, wherein
a leak for external air supply is formed in an underpressure area and a leak for air removal from the cabinet is formed in an overpressure area.

23. Assembly according to claim 20, wherein
a leak for external air supply is formed in an area of the suction side of a ventilator for the closed cooling air circuit, e.g. in an area alongside the heat exchanger connected to an exhaust air duct.

24. Assembly according to claim 20, wherein
the heat exchanger is an air-water heat exchanger located on the bottom side.

25. Assembly according to claim 22, wherein
the leak for air removal is formed in the area of the air exit side of the ventilator, e.g. downstream of the air-liquid heat exchanger.

26. Assembly according to claim 20, wherein
the external air supply and air removal, as a function of an atmospheric humidity measurement in the cooling air circuit of the cabinet, are controllable by the ambient conditions of the cabinet and the target values in the inner area of the cabinet.

27. Assembly according to claim 20, wherein
the interruptions for external air supply are formed in the sealing of the cable entry and/or cable exit in the area of a base or in a lower area of the cabinet, said area being in each case connected to a first exhaust air duct for a rising exhaust air flow.

28. Assembly according to claim 20, wherein
the interruptions for external air supply are formed in a shaft positioned alongside the heat exchanger and connected to the first exhaust air duct for the rising exhaust air flow.

29. Assembly according to claim 20, wherein
the seals of the cabinet are formed zonally lower than IP 55 and are water vapour-permeable for external air supply.

30. Method for air conditioning of electronic modular units located in an equipment and network cabinet, in which a cooling air flow is circulated in a closed circuit, cold supply air being supplied to the electronic modular units and heated exhaust air is cooled in a heat exchanger, wherein
the humidity of the air flow is stabilized by a defined supply of external air to prevent a continuous dehumidification of the air circulated in the closed circuit.

31. Method according to claim 30, wherein
the absolute humidity of the cooling air flow circulated in the closed circuit is measured and in the case of a deviation from a predeterminable value or range external air is supplied as a function of the ambient conditions of cabinet and the target values within the cabinet.

32. Method according to claim 30, wherein
the external air is supplied to the closed cooling air circuit through leaks or interruptions of the cabinet formed in a planned manner.

33. Method according to claim 30, wherein
the external air is supplied via leaks in areas in which prevail differential pressures between the cabinet interior and the environment of the cabinet.

34. Method according to claim 30, wherein
the external air is supplied in the area of cable entries and/or exits, e.g. in a base.

35. Method according to claim 34, wherein
the external air is supplied by means of leaks in the cabinet sealing, particularly in an area alongside the heat exchanger, which is an air-liquid heat exchanger and positioned at the bottom below the electronic modular units.

36. Method according to claim 30, wherein
the external air is supplied via openings in covering parts.

37. Method according to claim 30, wherein
for stabilizing the atmospheric humidity in the cabinet air is removed from said cabinet.

38. Method according to claim 37, wherein
air is removed from the cabinet by means of clearly defined openings or leaks in overpressure areas of said cabinet.
